(19) United States
(12) Patent Application Publication
(10) Pub. No.: US 2007/0104959 A1
(43) Pub. Date: May 10, 2007

(54) Liquid epoxy resin composition

(75) Inventors: Masatoshi Asano, Annaka-shi (JP); Kaoru Katoh, Annaka-shi (JP); Kazuaki Sumita, Annaka-shi (JP)

Correspondence Address: BIRCH STEWART KOLASCH & BIRCH, PO BOX 747, FALLS CHURCH, VA, 22040-0747, US

(73) Assignee: Shin-Etsu Chemical Co., Ltd., Tokyo (JP)

(21) Appl. No.: 11/590,801

(22) Filed: Nov. 1, 2006

(30) Foreign Application Priority Data
Nov. 1, 2005 (JP) 2005-318655
Nov. 21, 2005 (JP) 2005-336368
Nov. 22, 2005 (JP) 2005-336469
Oct. 17, 2006 (JP) 2006-283060

(51) Int. Cl. B32B 27/38; H01L 21/56; C08L 63/00; B32B 37/00

(52) U.S. Cl. 428/413; 438/127; 523/428; 525/476

(57) ABSTRACT

A liquid epoxy resin composition comprising (A) a liquid epoxy resin (B) an amine curing agent (C) a nitrogen compound selected from the group consisting of organic acids salts of tertiary amines, amino acids, imino acids, and monoamine compounds having an alcoholic hydroxyl group in an amount of from 0.1 to 20 parts by weight per total 100 parts by weight of the components (A) and (B), and (D) an inorganic filler in an amount of from 50 to 900 parts by weight per 100 parts by weight of the component (A).

This application claims benefit of Japanese Patent application No. 2005-318655 filed on Nov. 1, 2005, Japanese Patent application No. 2005-336368 filed on Nov. 21, 2005, Japanese Patent application No. 2005-336469 filed on Nov. 22, 2005, and Japanese Patent application No. 2006-283060 filed on Oct. 17, 2006, the contents of which are hereby incorporated by reference.

### FIELD OF THE INVENTION

The present invention relates to a liquid epoxy resin composition for encapsulating a semiconductor device. The present invention also relates to a semiconductor device encapsulated with the composition. The present composition is easy to handle and allows simplification of semiconductor device production process.

### BACKGROUND OF THE INVENTION

As semiconductor devices are getting smaller, thinner and lighter, more and more semiconductor chips are integrated in a device. The semiconductor chip is commonly mounted on a circuit board by flip-chip attach method. A typical flip-chip attach method is the controlled collapse chip connection (C4) process in which electrodes of the semiconductor chip is directly soldered with solder bumps or lands on a circuit board. After the soldering, the gap between the chip and the circuit board is sealed or encapsulated with an epoxy resin.

In conventional C4 process, the resin encapsulation is performed by capillary flow method. However, the process has drawback of low productivity due to many steps involved: 1) treatment of solder with flux, 2) soldering, 3) cleaning of the flux, 4) injection of an encapsulation resin by capillary flow method, and 5) curing of the resin. As pads are getting finer with narrower pitch, cleaning of the flux is getting more and more difficult. Residual flux on the circuit board respells an encapsulation resin, and ionic impurities in residual flux degrade reliability of a device package.

To solve these problems, U.S. Pat. No. 5,128,746 discloses a non-flow method in which soldering and resin encapsulation is performed in a single step by applying an encapsulation resin comprising flux component to a circuit board and then placing a semiconductor chip having solder electrodes on the applied resin.

For use in the non-flow method, various compositions comprising a curing agent performing as flux as well are proposed, for example, a phenolic resin as described in Japanese Patent Application Laid-Open No. 2002-232123, a phenolic carboxylic acid as described in Japanese Patent Application Laid-Open No. 2003-128874, an acid anhydride as described in Japanese Patent Application Laid-Open No. 2001-329048 and 2003-160639, a carboxylic acid as described in Japanese Patent Application Laid-Open No. 2002-293883 and an aromatic carboxylic acid hydrazide as described in Japanese Patent Application Laid-Open No. 2004-303874.

A composition comprising a flux component besides a curing agent are also known. For example, a composition comprising a carboxylic acid or a block carboxylic acid as flux component in addition to a phenolic or acid anhydride curing agent are known from Japanese Patent Application Laid-Open No. 2002-190497, 2003-82064, and 2001-223227.

### SUMMARY OF THE INVENTION

Most of the curing agents in the aforesaid compositions are phenolic or acid anhydrides curing agents. Comparing these curing agents, an amine curing agent generally can provide a cured product with stronger adhesion to a substrate and less exfoliation from the substrate or a semiconductor chip. In Japanese Patent Application Laid-Open No. 2002-293883, an amine adduct curing agent is examined but it is concluded that the amine adduct has no flux capability.

An object of the present invention is to provide a composition which comprises an amine curing agent and is advantageously used in the non-flow method.

The inventors have found that an epoxy composition comprising a specific nitrogen compound in combination with an amine curing agent is suitably used as an encapsulation resin in the non-flow method.

Thus, the present invention is a liquid epoxy resin composition comprising
(A) a liquid epoxy resin
(B) an amine curing agent
(C) a nitrogen compound selected from the group consisting of organic acids salts of tertiary amines, amino acids, imino acids, and monoamine compounds having an alcoholic hydroxyl group in an amount of from 0.1 to 20 parts by weight per total 100 parts by weight of the components (A) and (B), and
(D) an inorganic filler in an amount of from 50 to 900 parts by weight per 100 parts by weight of the component (A).

The present invention also provides a composition for encapsulating a flip-chip type semiconductor comprising the aforesaid present composition, and a flip-chip type semiconductor device comprising a cured product of the composition.

By comprising the nitrogen compound as a flux component in combination with an amine curing agent, the present liquid epoxy composition is suitable for use in the non-flow method for manufacturing flip-chip type semiconductor devices. The nitrogen compound does not react with the amine curing agent, so that the composition has a long potlife. Further, the nitrogen compound, unlike acidic flux, does not impair reliability of circuit.

### BRIEF DESCRIPTION OF THE DRAWING

FIG. 1 is a cross sectional view of a flip-chip type semiconductor device of the present invention.

### PREFERRED EMBODIMENTS OF THE INVENTION

Each component of the present composition is explained.

(A) Liquid Epoxy Resin

In the present invention, the liquid epoxy resin has at least two epoxy groups per molecule and is liquid including viscous liquid at room temperature. As the liquid epoxy resin, known epoxy resins can be used. Examples of the liquid epoxy resin include bisphenol A type epoxy resins, bisphenol AD type epoxy resins, bisphenol F type epoxy resins, naphthalene type epoxy resins, phenol novolac type epoxy resins, biphenyl type epoxy resins, glycidylamine epoxy resins, cycloaliphatic epoxy resins, dicyclopentadiene type epoxy resins, and a mixture of two or more of these. Among these, bisphenol A type epoxy resins, bisphenol F type epoxy resins, bisphenol AD type epoxy resins, and naphthalene type epoxy resins are preferred because of good resistance to heat and moisture.

Preferably, a total content of chlorine, originating from epichlorohydrin used to prepare the epoxy resin, of the epoxy resin is not more than 1500 ppm, more preferably not more than 1000 ppm. Further, a content of chlorine extractable with deionized water at 100° C. for 20 hours of the epoxy resin is not more than 10 ppm.

(B) Amine Type Curing Agent

In the present invention, the amine type curing agent has at least two active amino groups to react with the epoxy resin and form a cured product. Examples of the amine type curing agents include aromatic amines, aliphatic amines, polyamideamines, imidazols, and guanidines. Among these, aromatic amines are preferred because a composition containing an aromatic amine attains high adhesion strength to provide device packages resistant to heat and moisture.

Examples of preferred aromatic amine curing agent include 3,3′-diethyl-4,4′-diaminodiphenymethane, 3,3′,5,5′-tetramethyl-4,4′-diaminodiphenylmethane, 2,4-diaminotluene, 1,4-phenylenediamine, 1,3-phenylenediamine and a mixture of two or more of these.

An amine curing agent which is solid at room temperature is preferably melt mixed with the epoxy resin or other liquid amine curing agent prior to mixing with other components. The melt mixing is performed, in a later described mixing ratio of the epoxy resin with the curing agent, preferably at a temperature of from 70 to 150° C. for 1 to 2 hours. At a temperature below 70° C. or a time shorter than 1 hr, the solid amine may not be sufficiently mixed. Above 150° C. or a time longer than 2 hours, a reaction with the epoxy rein may occur, leading to increase in viscosity of a composition.

The amine curing agent is contained in the composition in such an amount that a molar ratio of epoxy groups of the epoxy resin (A) to active hydrogen atoms of the amine curing agent (B), [a molar amount of epoxy groups of the epoxy resin (A)/a molar amount of active hydrogen atoms of the amine curing agent (B)], ranges from 0.7 to 1.1, preferably from 0.8 to 1.0. When component (E), which is described later, is contained, a molar ratio of total epoxy groups of components (A) and (E) to active hydrogen of the amine curing agent, [a total molar amount of epoxy group of components (A) and (E)/a molar amount of active hydrogen of component (B)], ranges from 0.7 to 1.1, preferably from 0.8 to 1.0. When component (E) has a phenolic hydroxyl. group, a molar ratio of component (A) to total active hydrogen atoms of components (B) and (E), [a molar amount of component (A)/a total molar amount of active hydrogen of components (B) and (E)], ranges from 0.7 to 1.1, preferably from 0.8 to 1.0. If the ratio is below 0.7, there remain amino groups or phenolic hydroxyl groups unreacted, and a cured product may have a lower glass transition temperature and lower adhesion strength. If the ratio exceeds 1.1, a cured product is so brittle that it may crack during reflow process.

(C) Nitrogen Compounds

The present composition comprises at least one nitrogen compound selected from a group consisting of organic acids salts of tertiary amines, amino acids, imino acids, monoamine compounds having an alcoholic hydroxyl group. By incorporating the nitrogen compound in combination with the amine curing agent, the composition having flux performance and good storage stability can be obtained. Examples of the tertiary amines include alkylamines having two or more carbon atoms such as tri-n-butylamine and tri-n-octylamine, 1,5-diazabicyclo[4:3:0]nonene-5(DBN), 1,8-diazabicyclo[5:4:0]undecene-7(DBU), N-methylimidazol, and N-methylbenzimidazol.

Examples of organic acid include aliphatic monocarboxylic acids such as caproic acid, enanthic acid, caprylic acid, capric acid, undecanoic acid, tridecanoic acid, myristic acid, pentadecanoic acid, palmitic acid, heptadecanoic acid, nonadecanoic acid, arachic acid, isocaprylic acid, propyl valeric acid, ethyl capric acid, 2,2-diethylbutanonic acid, 2,2-dimethylpentanoic acid, 2,2-dimethylhexanoic acid, 2,2-dimetehyloctanoic acid, 2-methyl-2-ethylbutanoic acid, 2-methyl-2-ethyl pentanoic acid, 2-methyl-2-ethylhexanoic acid, 2-methyl-2-ethylheptanoic acid, 2-methyl-2-propylpentanoicacid, 2-methyl-2-propylhexanoicacid, 2-methyl-2-propylheptanoic acid, octylic acid, octenoic acid, oleic acid, cyclopentanoic acid, and cyclohexanoic acid; aliphatic polycarboxylic acids such as oxalic acid, malonic acid, succinic acid, glutaric acid, adipic acid, pimelic acid, suberic acid, azelaic acid, sebacic acid, methylmalonic acid, ethylmalonic acid, methylsuccinic acid, ethylsuccinic acid, 2,2-dimethylsuccinic acid, 2,3-dimethylsuccinic acid, 2-methylglutaric acid, 3-methylglutaric acid, maleic acid, citraconicacid, itaconic acid, methleneglutaric acid, 1,5-octanedicarboxylic acid, 5,6-decanedicarboxylic acid, 1,7-decanedicarboxylic acid, 4,6-dimethyl-4-nonene-1,2-dicarboxylic acid, 4,6-dimethyl-1,2-nonanedicarboxylic acid, 1,7-dodecanedicarboxylic acid, 5-ethyl-1,10-decanedicarboxylic acid, 6-methyl-6-dodecene-1,12-dicarboxylic acid, 6-methyl-1,12-dodecanedicarboxylic acid, 6-ethyl-1,12-dodecanedicarboxylic acid, 6-ethyl-1,12-dodecanedicarboxylic acid, 7-methyl-7-tetradecene-1,14-dicarboxylic acid, 7-methyl-1,14-tetradecanedicarboxylic acid, 3-hexyl-4-decene-1,2-dicarboxylic acid, 3-hexyl-1,2-decanedicarboxylic acid, 6-ethyl-9-hexadecene-1,16-dicarboxylic acid, 6-ethyl-1,16-hexadecanedicarboxylic acid, 6-phenyl-1,12-dodecanedicarboxylic acid, 7,12-dimethyl-7,11-octadecadiene-1,18-dicarboxylic acid, 7,12-dimethyl-1,18-octadecanedicarboxylic acid, 6,8-diphenyl-1,14-tetradecanedicarboxylic acid, 1,1-cyclopentadicarboxylic acid, 1,2-cyclopentadicarboxylic acid, 1,1-cyclohexadicarboxylic acid, 1,2-cyclohexadicarboxylic acid, 4-cyclohexene-1,2-dicarboxylic acid, 5-norbornene-2,3-dicarboxylic acid, and malicacid; aromatic monocarboxylic acids such as benzoic acid, toluic acid, ethylbenzoic acid, propylbenzoic acid, isopropylbenzoic acid, butylbenzoic acid, isobutylbenzoic acid, hydoroxybenzoic acid, anisic acid, ethoxybenzoic acid, propoxybenzoic acid, isopropoxybenzoic acid, butoxybenzoic acid, isobutoxybenzoic acid, nitrobenzoic acid, and resorcinol acid; aromatic polycarboxylic acid such as phthalic acid, nitorophthalic acid, trimellitic acid; and phenol derivatives such as β-naphthol, o-nitrophenol, p-nitrophenol, catechol, resorcin, 4,4′-dihydroxydiphenyl-2,2-propane, phenol novolac, and cresol novolac.

The tertiary amine and the organic acid may be a mixture of two or more of amines or acids. Preferably, a monocarboxylic acid salt of DBU or DBN is used because long pot life of the composition can be attained. A fatty monocarboxylic acid salt of DBU and a fatty monocarboxylic acid salt of DBN are particularly preferred because the salts are mostly liquid and easy to incorporate in the composition.

An amino acid has at least one carboxylic group and at least one amino group per molecule. An imino acid has at least one carboxylic group and at least one imino group and is categorized as amino acid in the broad sense. It has been found that these compounds have higher flux capability than organic acids conventionally used as flux. Many amino acids or imino acids have a high melting temperature but can be incorporated in the composition by dissolving in liquid components such as liquid amine curing agent.

Amino Acids are commonly classified into neutral amino acids, basic amino acids, acidic amino acids, and amides of acidic amino acids. Among these, the neutral amino acids and the amides of acidic amino acids are preferred because a composition comprising such an amino acid is storage stable, showing little change in viscosity. Examples of basic amino acid include lysine, and arginine; examples of acidic amino acid include aspartic acid, and glutamic acid; examples of neutral amino acid include isoleucine, glycine, alanine, serine, glutamine, aminobenzoic acid, and phenylalanine; and an example of heterocyclic imino acid is proline. Among these isoleucine, glycine, alanine, serine, arginine, glutamine and aminobenzoic acid are preferred.

The alcohol amine in the present invention has at least one amino group, imino group or substituted amino group per molecule. Preferably, those having a boiling point high enough or a vapor pressure low enough not to vaporize during soldering or resin encapsulation process to cause voids in cured product.

Examples of the alcoholic amine include 3-amino-1-propanol, 5-amino-1-pentanol, 6-amino-1-hexanol, N-methyldiethanolamine, triethanolamine, 4-amino-2-methylbutanol, 2-(2-aminoethoxy) ethanol, 2-(2-aminoethylamino)ethanol, 4-ethylamino-1-butanol, 2-amino-1-phenylethanol, 1-(3-aminophenyl)ethanol, 3-amino-2, 2-dimethyl-1-propanol, 2-amino-2-methyl-1,3-propanediol, 2-amino-2-ethyl-1,3-propanediol, N-(2-hydroxyethyl)morpholine, N-(2-hydroxypropyl)morpholine, 1-piperazine ethanol, 1-piperizine ethanol, 2-piperazine ethanol, and 4-piperizine ethanol, among which 2-amino-2-methyl-1,3-propanediol, 2-amino-1-phenylethanol, triethanolamine are preferred.

The nitrogen compound (C) is incorporated in the composition in an amount of from 0.1 to 20 parts by weight, preferably from 1 to 10 parts by weight per total 100 parts by weight of components (A) and (B). If it is contained in an amount less than 0.1 part by weight, sufficient performance as flux may not be attained. If it is contained in am amount more than 20 parts by weight, a cured product may have too low glass transition temperature or adhesion strength.

A nitrogen compound (C) which is solid at room temperature, particularly when it is contained in a relatively larger amount, is preferably melt mixed with the liquid epoxy resin or liquid amine curing agent prior to mixing with other components. The melt mixing is preferably performed at a temperature of from 70 to 150° C. for 1 to 2 hours. Many amino acids or imino acids have a relatively higher melting point and do not dissolve in the liquid epoxy resin or the liquid amine curing agent. Such amino acids or imino acids may be incorporated in the composition in the form of solid after pulverized.

(D) Inorganic filler

By containing the inorganic fillers, a cured product of the composition has a reduced thermal expansion coefficient. Any known filler can be used, for example, fused silica, crystalline silica, alumina, titanium dioxide, silica/titania, boron nitride, aluminum nitride, silicon nitride, magnesia, magnesium silicate, aluminum and a mixture of two or more of these. Preferably, spherical fused silica is used because of a lower viscosity of a composition containing the fused silica.

The inorganic filler is preferably pretreated with a coupling agent such as silane coupling agent or titanate coupling agent to increase affinity to the resins. Preferably, silane coupling agents are used whose examples include epoxy silanes such as γ-glycidoxypropyltrimethoxysilane, γ-glycidoxypropylmethyldiethoxysilane, β-(3,4-dpoxycyclohexyl)ethyltrimethoxysilane; aminosilanes such as N-β(aminoethyl)-γ-aminopropyltrimethoxysilane, γ-aminopropyltriethoxysilane, N-phenyl-γ-aminopropyltrimethoxysilane; and mercaptosilanes such as γ-mercaptosilane.

The inorganic filler is contained in the composition in an amount of from 50 to 900 parts by weight, preferably from 100 to 500 parts by weight per 100 parts by weight of the epoxy resin. A composition containing the filler in an amount below the aforesaid lower limit gives a cured product which may have larger expansion coefficient which may crack in a heat cycle test. A composition containing the filler in an amount above the aforesaid upper limit may has higher viscosity which tends to form voids in a cured product. Further, the filler may inhibit solder connection.

The present composition may contain the following components in an amount not to adversely affect the composition.

(E) Silicone-Modified Epoxy Resin

The present composition may contain a silicone-modified epoxy resin as a flexibilizer to make a cured product flexible. Examples of the flexibilizer include silicone resins in the form of powder, rubber, and oil, thermoplastic resins such as liquid polybutadiene rubber and acrylic core-shell resin. Preferably, the silicone-modified epoxy resin is used. Particularly, a addition reaction product of an epoxy resin or a phenolic resin with an organopolysiloxane. The epoxy resin or a phenolic resin has an alkenyl group and is represented by the following formulas (1), (2), (3) or (4). 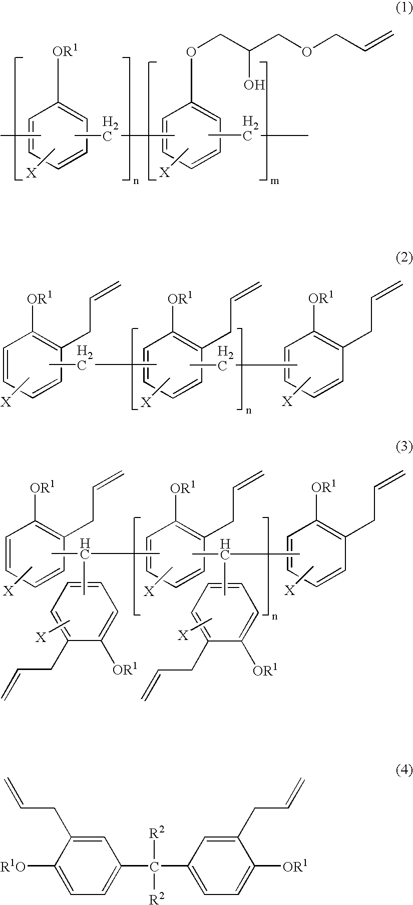
wherein R¹ is a hydrogen atom or the group shown below, 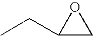
R² is a hydrogen atom or a methyl group, X is a hydrogen atom or a monovalent hydrocarbon group having 1 to 6 carbon atoms, n is an integer of from 0 to 50, preferably from 1 to 20, and m is an integer of from 1 to 5, preferably 1, and the organopolysiloxane is represented by the following average compositional formula
H_{aR}³_{b}SiO_{(4-a-b)/2} (5)
wherein R³ is a substituted or unsubstituted monovalent hydrocarbon group, a is a number of from 0.01 to 0.1, b is a number of from 1.8 to 2.2, with a sum of a and b ranging from 1.81 to 2.3, which organopolysiloxane has 10 to 400 silicon atoms and 1 to 5 SiH bonds per molecule.

Preferred R³ is a monovalent hydrocarbon group having 1 to 10, particularly, 1 to 8 carbon atoms. Examples of such a group include alkyl groups such as methyl, ethyl, propyl, isopropyl, butyl, isobutyl, tert-butyl, hexyl, octyl, and decyl groups; alkenyl groups such as vinyl, allyl, propenyl, and hexenyl groups; aryl groups such as phenyl, xylyl, and tolyl groups; aralkyl groups such as benzyl, phenylethyl, and phenylpropyl groups, and partially or fully halogen substituted groups thereof such as fluoromethyl, bromoethyl, and trifluoropropyl groups.

A preferred silicone-modified epoxy resin is represented by the following formula (6).

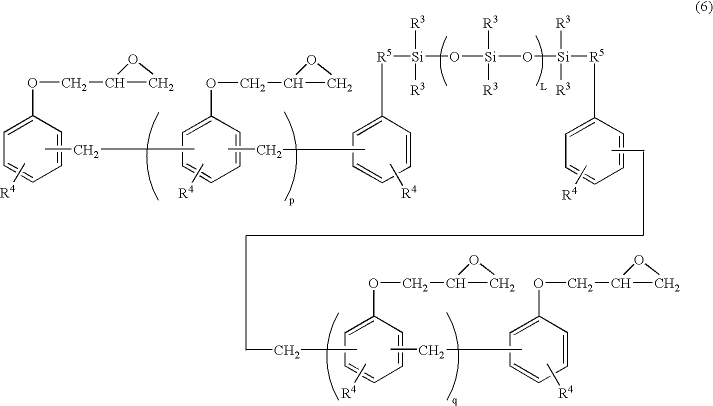

In the above formula (6), R⁴ is a hydrogen atom or a monovalent hydrocarbon group having 1 to 6 carbon atoms, and R⁵ is a divalent group represented by the formula, —CH₂CH₂CH₂—, —OCH₂—CH(OH)—CH₂—O—CH₂CH₂CH₂— or —O—CH₂CH₂CH₂—. L is an integer of from 8 to 398, preferably from 18 to 198 and p is an integer of from 1 to 10, and q is an integer of from 1 to 10.

Examples of R⁴ include alkyl groups such as methyl, ethyl, propyl, isopropyl, butyl, isobutyl, tert-butyl, hexyl, octyl, and decyl groups; cycloalkyl groups such as cyclopentyl and cyclohexyl groups; alkenyl groups such as vinyl, allyl, propenyl, and hexenyl groups; and aryl groups such as phenyl group, among which methyl group is preferred. R^{4′} may be different from each other.

In the formula (6), p and q are integers of from 1 to 10, preferably from 1 to 5. If p and/or q is larger than 10, a cured product may be too hard, resulting in cracking, weak adhesion or low reliability of a device package.

In the formula (6), L is an integer of from 8 to 398, preferably from 18 to 198. A silicone-modified resin with L being less than 8 is not sufficiently flexible due to too little portion of polysiloxane moieties in a molecule. A resin with L being larger than 398 may be difficult to disperse in a composition, and a composition obtained has unstable quality.

Component (E) is incorporated in the composition in an amount of 20 parts by weight or less, particularly from 2 to 15 parts by weight, per 100 parts by weight of component (A) to attain sufficient flexibilizing effect.

Optional Additives

The present composition may contain optional additives such as cure promoters, surfactants, antifoaming agents, leveling agents, ion trap agents, pigments such as carbon black, and dye stuffs, in an amount not to adversely affect the composition.

The present composition can be prepared by mixing the liquid epoxy resin (A), the amine curing agent (B), nitrogen compound (C), inorganic filler (D), and optional additives in a batch process or a serial process. Any mixing means can be used such as an automatic mortar equipped with a stirrer and a heater, a three-roller mill, a ball mill, and a planetary mixer. These mixing means may be used in combination.

The present liquid epoxy composition has a viscosity of 1000Pa·s or smaller, particularly of 500 Pa·s or smaller, at 25° C. The composition is preferably cured at a temperature of from 100 to 120° C. for about 0.5 hour and then at a temperature of from 150 to 175° C. for about 0.5 to 4 hours. The first heating step ensures to obtain a cured product without voids. If a period of time of the second heating step at 150 to 175° C. is shorter than 0.5 hour, cured product may not have satisfactory properties.

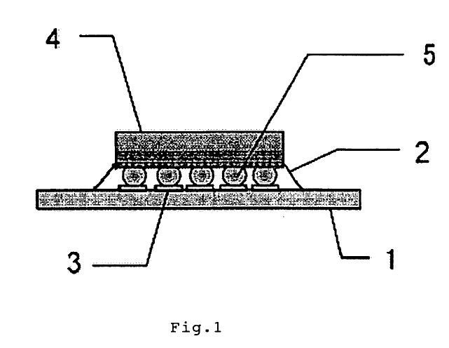

FIG. 1 shows an example of a flip-chip type semiconductor package. In the package, a semiconductor chip 3 is mounted on a surface of an organic substrate having a circuit pattern via a plurality of solder bumps 2. The gap between the organic substrate 1 and the semiconductor chip 3 is filled or encapsulated with an underfill 4. The present composition is particularly useful as an underfill adhesive.

When the present liquid epoxy resin composition is used as an underfill, the composition forms a cured product having a coefficient of thermal expansion preferably of from 20 to 40 ppm/° C. at a temperature not higher than its glass transition temperature.

### EXAMPLES

The present invention will be explained with reference to the examples but not limited thereto. In the following description, % means wt % and parts means parts by weight, unless otherwise specified.

The following substances are used.

(A) Liquid Epoxy Resin

Epoxy resin (a): Bisphenol F type epoxy resin having an epoxy equivalent of 170, RE303S-L, ex Nippon Kayaku Co., Ltd. Epoxy resin (b): Trifunctional epoxy resin of the following formula (7) having an epoxy equivalent of 101, Epikote 630H, Japan Epoxy Resin Co. 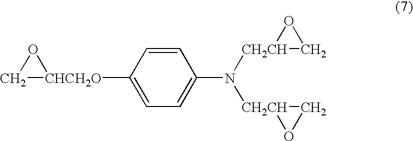
(B) Curing Agent

Diethyldiaminodiphenylmethane having an amine equivalent of 63.5, Kayahard A-A, Nippon Kayaku Co., Ltd

(C) Nitrogen Compound

Each number corresponds to example number.
1. DBU/octanoic acid salt, U-CAT SA102, ex San-apro Co.
2. DBU/octanoic acid salt, U-CAT 1102, ex San-apro Co.
3. DBU/o-phthalic acid salt, U-CAT SA810, ex San-apro Co.
4. 3-aminobenzoic acid, ex Tokyo Chemical Industry Co., Ltd.
5. β-alanine, ex Tokyo Chemical Industry Co., Ltd.
6. DL-proline, ex Tokyo Chemical Industry Co., Ltd.
7. L-glutamic acid, ex Tokyo Chemical Industry Co., Ltd.
8. L-glutamine, ex Tokyo Chemical Industry Co., Ltd.
9. 2-amino-2-methyl-1,3-propanediol, ex Tokyo Chemical Industry Co., Ltd.
10. 2-amino-1-phenylethanol, ex Tokyo Chemical Industry Co., Ltd.
11. Triethanolamine, ex Tokyo Chemical Industry Co., Ltd.
12. 4-piperidinoethanol
13. 3-Morpholino-1,2-propanediol
   (D) Inorganic Filler

Spherical silica having an average particle diameter of 2 μm and a maximum particle diameter of 10 μm, ex Tatsumori Ltd.

(E) Silicone-Modified Epoxy Resin

An addition polymerization product of the compound of the following formula (8) with the compound of the formula (9). 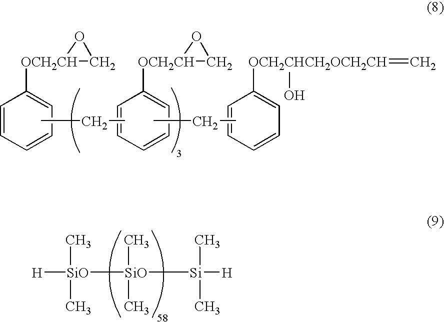
Other Additives

Carbon black: Denka black, ex Denki Kagaku Kogyo Kabushiki Kaisya Silane coupling agent: γ-glycidoxypropyltrimethoxysilane, KBM403, ex Shin-Etsu Chemical Co. Ltd.

Compounds Used in Comparative Examples

Each number corresponds to comparative example number.
1. Abietic acid
2. Salicylic acid
3. Glycerol
4. 1,6-hexanediol

### Example 1

Using a planetary mixer, 31.8 parts by weight of the epoxy resin (a), 31.8 parts by weight of the epoxy resin (b), 33 parts by weight of the curing agent, i.e., diethyldiaminodiphenylmethane, 2 parts by weight of nitrogen compound 1, 100 parts by weight of the spherical silica, 4 parts by weight of the silicone-modified epoxy resin, 1 part by weight of the silane coupling agent, and 1 part by weight of the carbon black were thoroughly mixed and then kneaded with a three-roller mill to well disperse solid substances. The mixture obtained was deaerated under vacuum, whereby a liquid epoxy resin composition was obtained.

### Examples 2-13

Compositions were prepared in the same manner as in Example 1 except that the nitrogen compounds 2 to 13, respectively in Examples 2 to 13, were used in place of the nitrogen compound 1. The nitrogen compound 4, 3-aminobenzoic acid was melt mixed in diethyldiaminodiphenylmethane in advance, and the nitrogen compounds 5 to 7 were pulverized into fine powder in advance, and then mixed with other components.

### Comparative Examples 1 to 5

Compositions were prepared in the same manner as in Example 1 except that the nitrogen compounds 1 to 4, respectively in Comparative Examples 1 to 4, were used in place of the nitrogen compound 1, and none of the nitrogen compounds was added in Comparative Example 5. Abietic acid and salicylic acid were melt mixed with the epoxy resins in advance and then mixed with other components.

Each composition was evaluated according to the following methods.

(1) Viscosity

Using a BH type rotating viscometer, viscosity at 25° C. was measured at 4 rpm.

(2) Storage Stability

Each composition was kept in an atmosphere of 25° C. and a 60% RH for 48 hours. Potlife, i.e., a length of time a composition retains viscosity low enough to be processed, of each composition was rated according to the following criteria.
A: Long potlife with less than 30% change in viscosity from the initial viscosity
B: A little bit short potlife with 30 to 50% change in viscosity from the initial viscosity
C: Short potlife with more than 100% change in viscosity from the initial viscosity
   Viscosity was measured in the same manner as described (1) above.
   (3) Adhesion Strength

On a silicon chip coated with cured photosensitive polyimide resin, each composition was molded in the shape of a circular truncated cone with a top surface diameter of 2 mm, a basal surface diameter of 5 mm and a height of 5 mm, by heating at 120° C. for 0.5 hour and then 165° C. for 3 hours. Initial adhesion strength of the molded product to the silicone chip was measured by pushing the side surface of the molded product at 0.2 mm/sec. This test piece was then placed in a pressure cooker tester and kept in an atmosphere of 121° C. and 2.1 atm for 336 hours. After taking out the test piece from the pressure cooker tester, adhesion strength of the molded product to the silicon chip was measured in the aforesaid method. Total five test pieces were tested and the obtained data were averaged.

(4) Soldering Property

A flip-chip type semiconductor chip having four sections per chip with 576 Sn3.0/Ag0.5/Cu solder bumps per section and a substrate were used. Each composition was applied on the substrate with a dispenser, on which the semiconductor chip was mounted with a flip-chip bonder at a soldering temperature of 260° C. for 3 seconds with 10N load. Then, the applied composition was cured at 120° C. for 0.5 hour and then 165° C. for 3 hours. Electrical connection of the semiconductor test piece thus obtained was examined. Total 10 test pieces, i.e., total 40 sections, were prepared for each composition and the number of sections was counted in which electrical connection via solder was confirmed.

(5) Void

The test pieces prepared in the above test were observed with a supersonic flow detector for voids. The number of chips in which a void was found were counted.

(6) Exfoliation

Among the test pieces prepared for the soldering property test, total 10 semiconductor chips without a void were kept in an atmosphere of 30° C. and 65% RH for 192 hours. Then, the test pieces were passed in an IR reflow furnace with a peak temperature of 265° C. for five times and then observed for cracks or exfoliation with the super sonic flow detector. The number of chips without cracks and exfoliation was counted. Subsequently, the test pieces were kept in an atmosphere of 121° C. at 2.1 atm in a pressure cooker tester for 336 hours and observed for cracks or exfoliation with the super sonic flow detector. The number of chips without a crack and exfoliation was counted.

(7) Temperature Cycle Test

Among the test pieces prepared in the soldering property test, total 10 semiconductor chips without a void were kept in an atmosphere of 30° C. and 65% RH for 192 hours and then subjected to a heat cycle test in which one cycle consisted of cooling at −65° C. for 30 minutes and then heating at 150° C. for 30 minutes, for 250, 500, 750 and 1000 cycles. The chips were observed for cracks or exfoliation and the number of chips without a crack and exfoliation was counted.

The results are as shown in Tables 1 and 2. The compositions of Comparative examples 2 and 3 were not subjected to the exfoliation and the temperature cycle tests because voids were observed in too many test pieces.

TABLE 1

| | | Example | | | | | | | | | | | | |
|---|---|---|---|---|---|---|---|---|---|---|---|---|---|---|
| | | 1 | 2 | 3 | 4 | 5 | 6 | 7 | 8 | 9 | 10 | 11 | 12 | 13 |
| Viscosity | | 45 | 47 | 57 | 53 | 60 | 59 | 63 | 61 | 55 | 57 | 47 | 55 | 59 |
| (Pa · s, 25° C.) | | | | | | | | | | | | | | |
| Sorage stability | | A | A | A | A | A | A | B | A | A | A | B | A | A |
| Adhesion | Initial | 1560 | 1500 | 1420 | 1420 | 1410 | 1500 | 1440 | 1470 | 1410 | 1470 | 1450 | 1400 | 1430 |
| strength | PCT 336 hr | 1360 | 1330 | 1250 | 1260 | 1250 | 1330 | 1250 | 1280 | 1250 | 1280 | 1300 | 1270 | 1210 |
| (MPa) | | | | | | | | | | | | | | |
| Soldering properety | | 40/40 | 38/40 | 40/40 | 40/40 | 40/40 | 38/40 | 40/40 | 40/40 | 40/40 | 38/40 | 40/40 | 36/40 | 37/40 |
| Void | | 0/10 | 0/10 | 0/10 | 0/10 | 0/10 | 0/10 | 0/10 | 0/10 | 0/10 | 0/10 | 0/10 | 0/10 | 0/10 |
| Exfolia- | IR furnace | 0/10 | 0/10 | 0/10 | 0/10 | 0/10 | 0/10 | 0/10 | 0/10 | 0/10 | 0/10 | 0/10 | 0/10 | 0/10 |
| tion | 5 passes | | | | | | | | | | | | | |
| | PCT 336 hr | 0/10 | 0/10 | 0/10 | 0/10 | 0/10 | 0/10 | 0/10 | 0/10 | 0/10 | 0/10 | 0/10 | 0/10 | 0/10 |
| Temper- | 250 cycles | 0/10 | 0/10 | 0/10 | 0/10 | 0/10 | 0/10 | 0/10 | 0/10 | 0/10 | 0/10 | 0/10 | 0/10 | 0/10 |
| ature | | | | | | | | | | | | | | |
| cycle | 500 cycles | 0/10 | 0/10 | 0/10 | 0/10 | 0/10 | 0/10 | 0/10 | 0/10 | 0/10 | 0/10 | 0/10 | 0/10 | 0/10 |
| | 750 cycles | 0/10 | 0/10 | 0/10 | 0/10 | 0/10 | 0/10 | 0/10 | 0/10 | 0/10 | 0/10 | 0/10 | 0/10 | 0/10 |
| | 1000 cycles | 0/10 | 0/10 | 0/10 | 0/10 | 0/10 | 0/10 | 0/10 | 0/10 | 0/10 | 0/10 | 0/10 | 0/10 | 0/10 |

TABLE 2

| | | Comparative example | | | | |
|---|---|---|---|---|---|---|
| | | 1 | 2 | 3 | 4 | 5 |
| Viscosity | | 58 | 55 | 48 | 59 | 50 |
| (Pa · s, 25° C.) | | | | | | |
| Sorage stability | | C | B | A | A | A |
| Adhesion strength | Initial | 1480 | 1520 | 1400 | 1420 | 1450 |
| (MPa) | PCT 336 hr | 1290 | 1240 | 1220 | 1230 | 1300 |
| Soldering properety | | 37/40 | 9/40 | 0/40 | 0/40 | 0/40 |
| Void | | 0/10 | 8/10 | 7/10 | 0/10 | 0/10 |
| Exfoliation | IR furnace | 0/10 | | | 0/10 | 0/10 |
| | 5 passes | | | | | |
| | PCT 336 hr | 0/10 | | | 0/10 | 0/10 |
| Temperature cycle | 250 cycles | 0/10 | | | 0/10 | 0/10 |
| | 500 cycles | 0/10 | | | 0/10 | 0/10 |
| | 750 cycles | 0/10 | | | 0/10 | 0/10 |
| | 1000 cycles | 0/10 | | | 0/10 | 0/10 |

As can be seen from Tables 1and 2, the epoxy resin composition of each Example was excellent in adhesion strength and soldering property. It gave a cured product without a void to provide reliable device package. Storage stability was very good, although the composition of Example 7 which contained an acidic amino acid was not so good.

On the other hand, the compositions of Comparative Examples 1 and 2 showed bad storage stability due to the carboxylic acids contained. Further, the composition of Comparative Example 2 comprising salicylic acid showed bad soldering property and gave a cured product with many voids.

1. A liquid epoxy resin composition comprising
(A) a liquid epoxy resin
(B) an amine curing agent
(C) a nitrogen compound selected from the group consisting of organic acids salts of tertiary amines, amino acids, imino acids, and monoamine compounds having an alcoholic hydroxyl group in an amount of from 0.1 to 20 parts by weight per total 100 parts by weight of the components (A) and (B), and
(D) an inorganic filler in an amount of from 50 to 900 parts by weight per 100 parts by weight of the component (A).

2. The composition according to claim 1, wherein the tertiary amine is selected from the group consisting of alkylamines having two or more carbon atoms, 1,5-diazabicyclo[4:3:0]nonene-5,1,8-diazabicyclo[5:4:0]undecene-7, and N-methylimidazol and derivatives thereof.

3. The composition according to claim 1, wherein the amino acid is selected from the group consisting of neutral amino acids and amides of acidic amino acids.

4. The composition according to claim 1, wherein the imino acid is a heterocyclic imino acid.

5. The composition according to claim 1, wherein the monoamine compound having an alcoholic hydroxyl group is selected from the group consisting of C₃₋₈ aliphatic or aromatic aminoalocohols, morpholino alcohols and piperizino alcohols.

6. The composition according to any one of claims 1 to 5, wherein the amine curing agent (B) is an aromatic amine.

7. The composition according to any one of claims 1 to 5, wherein the composition further comprises (E) a silicone-modified epoxy resin represented by the following formula (6) in an amount of from 0 to 20 parts by weight per 100 parts by weight of the component (A) 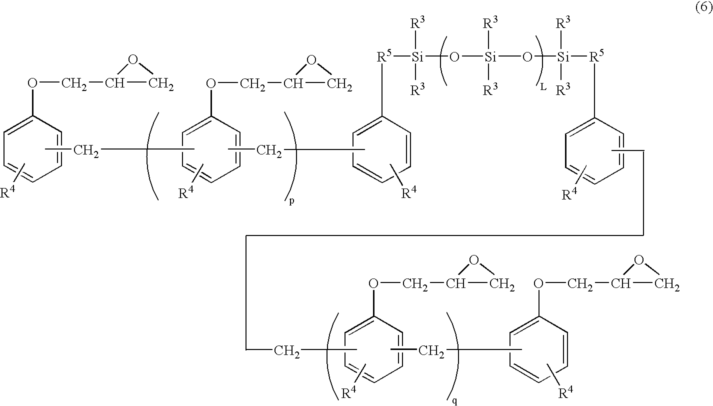
wherein R₄ is a hydrogen atom or a monovalent hydrocarbon group having 1 to 6 carbon atoms, R⁵ is a divalent group represented by the formula, —CH₂CH₂CH₂—, —OCH₂—CH(OH)—CH₂—O—CH₂CH₂CH₂—, or —O—CH₂CH₂CH₂—, L is an integer of from 8 to 398, p is an integer of from 1 to 10, and q is an integer of from 1 to 10.

8. The composition according to claim 1, wherein the composition is a composition for encapsulating a flip-chip type semiconductor.

9. A flip-chip type semiconductor device comprising a cured product of the composition according to claim 8.
